(19) United States
(12) Patent Application Publication
(10) Pub. No.: US 2017/0166730 A1
(43) Pub. Date: Jun. 15, 2017

(54) LIGHT-REFLECTING WHITE HEAT-CURABLE EPOXY RESIN COMPOSITION AND OPTICAL SEMICONDUCTOR DEVICE USING SAME

(71) Applicant: Shin-Etsu Chemical Co., Ltd., Tokyo (JP)

(72) Inventors: Yoshihiro TSUTSUMI, Annaka-shi (JP); Tadashi TOMITA, Annaka-shi (JP)

(73) Assignee: Shin-Etsu Chemical Co., Ltd., Tokyo (JP)

(21) Appl. No.: 15/374,073

(22) Filed: Dec. 9, 2016

(30) Foreign Application Priority Data
Dec. 10, 2015 (JP) 2015-241199

(51) Int. Cl. C08K 13/06; H01L 33/60

(52) U.S. Cl. CPC C08K 13/06; H01L 33/60

(57) ABSTRACT

Provided is a light-reflecting white heat-curable epoxy resin composition capable of forming a cured product that can maintain a high reflectivity and whiteness over a long period of time. The composition can be pressure-molded at a room temperature, and contains:
(A) a prepolymer as a reaction product of a triazine derivative epoxy resin (A-1) and a non-aromatic and carbon-carbon double bond-free acid anhydride (A-2), wherein a ratio of a total sum of epoxy groups in the component (A-1) to a total sum of acid anhydride groups in the component (A-2) is 0.6 to 2.0;
(B) a white pigment;
(C) an inorganic filler other than the white pigment (B);
(D) a curing accelerator;
(E) at least one antioxidant selected from a phenolic antioxidant, a phosphorous antioxidant and a sulfur-based antioxidant; and
(F) a hydrotalcite-like compound and/or a calcined product of a hydrotalcite-like compound.

### BACKGROUND OF THE INVENTION

Field of the Invention

The present invention relates to a white heat-curable epoxy resin composition, particularly to a light-reflecting white heat-curable epoxy resin composition and an optical semiconductor device using the same.

Background Art

Optical semiconductor elements such as LEDs (Light Emitting Diode) have been used as various indicators and light sources such as displays on the streets, automobile lamps and residential lightings. Among them, white LEDs are being developed rapidly in various fields under the slogans of carbon dioxide reduction and energy saving.

As one material for use in semiconductor and electronic devices such as LEDs, there has been used a reflector material, an example of which being a polyphthalamide resin (PPA) that is widely used even today. Reflector materials using PPA have such a high strength and flexibility that they are excellent in handling property. They, however, have extremely poor heat and light resistances, and thus easily get discolored. For this reason, PPA undergoes severe deterioration such as discoloration when used around optical semiconductor elements, causing a reduction of optical output, etc. and hence it has not been a satisfactory material for illumination or automobile uses in the past (see JP-A-2006-257314).

JP-B-2656336 discloses an optical semiconductor device using, as an optical semiconductor element encapsulating resin, a B-stage epoxy resin composition comprised of an epoxy resin, a curing agent and a curing accelerator, serving as encapsulation resin composition for optical semiconductor elements, and having a cured body of the resin composition in which the foregoing constituents are uniformly mixed on the molecular level. This composition mainly uses a bisphenol A-type epoxy resin or a bisphenol F-type epoxy resin as the epoxy resin. Though JP-B-2656336 also discloses that triglycidyl isocyanate or the like may be used, triglycidyl isocyanate in its working examples is added in small amounts to the bisphenol type epoxy resins, and examinations by the inventors of the present invention show that there has been a problem that such B-stage epoxy resin composition for encapsulating a semiconductor turns yellow particularly when left under a high temperature for a long period of time.

JP-A-2000-196151 discloses an LED encapsulated by an alicyclic epoxy resin obtained by oxidizing a cyclic olefin. JP-A-2003-224305 discloses an epoxy resin composition for encapsulating a light-emitting element that contains a triazine derivative epoxy resin and an acid anhydride curing agent. JP-A-2005-306952 discloses an epoxy resin composition for encapsulating a light-emitting element that contains: (A) an epoxy resin containing a hydrogenated epoxy resin, a triazine ring-containing epoxy resin and an alicyclic epoxy resin obtained by epoxidizing an alicyclic olefin; and (B) an acid anhydride curing agent. However, a higher resistance to discoloration is desired even in the epoxy resin composition for encapsulating a light-emitting element as disclosed in JP-A-2000-196151, JP-A-2003-224305 and JP-A-2005-306952.

JP-A-2015-101614 discloses that a triazine derivative epoxy resin is also used in an epoxy resin composition for reflector materials, in which a combination of several kinds of antioxidants is added in order to improve resistance to discoloration, thereby obtaining a high heat resistance. However, an even higher resistance to discoloration is desired in use applications where a long-term reliability is desired, such as those for illumination or automobile use.

### SUMMARY OF THE INVENTION

It is, therefore, an object of the present invention to provide a white heat-curable epoxy resin composition having a superior handling property, heat resistance and light resistance, enabling one to obtain a cured product that can maintain a high reflectivity as well as a high whiteness level over a long period of time. It is another object of the present invention to provide a semiconductor device whose light receiving element and other semiconductor elements are encapsulated by a cured product of such composition.

As a result of extensive studies to achieve the abovementioned objects, the inventors of the present invention found that it is possible to attain the objects by adding a hydrotalcite-like compound and/or a calcined product of a hydrotalcite-like compound to a white heat-curable epoxy resin composition including a prepolymer obtained by a reaction of a triazine derivative epoxy resin and an acid anhydride, and hence completed the present invention.

That is to say, the present invention provides the following light-reflecting white heat-curable epoxy resin composition, and a semiconductor device using the same.

[1]

A light-reflecting white heat-curable epoxy resin composition capable of being pressure-molded at a room temperature, comprising:
(A) a prepolymer as a reaction product of a triazine derivative epoxy resin (A-1) and a non-aromatic and carbon-carbon double bond-free acid anhydride (A-2), wherein a ratio of a total sum of epoxy groups in the component (A-1) to a total sum of acid anhydride groups in the component (A-2) is 0.6 to 2.0;
(B) a white pigment;
(C) an inorganic filler other than the white pigment (B);
(D) a curing accelerator;
(E) at least one antioxidant selected from a phenolic antioxidant, a phosphorous antioxidant and a sulfur-based antioxidant; and
(F) a hydrotalcite-like compound and/or a calcined product of a hydrotalcite-like compound.
   [2]

The light-reflecting white heat-curable epoxy resin composition as set forth in [1], wherein the hydrotalcite-like compound and/or the calcined product of the hydrotalcite-like compound (F) is represented by the following general formula (4):

MgₐAl_{b}(OH)_{c}CO₃.nH₂O (4)

wherein a, b and c represent numbers larger than 0, provided that 2a+3b-c=2, and n represents a number satisfying an inequality: 0≦n≦4.
[3]

The light-reflecting white heat-curable epoxy resin composition as set forth in [1] or [2], wherein the white pigment (B) is a titanium dioxide that has been surface-treated with alumina, and further with at least one selected from the group consisting of silica, alumina, zirconia, polyol and a silicon compound.

[4]

The light-reflecting white heat-curable epoxy resin composition as set forth in any one of [1] to [3], wherein the triazine derivative epoxy resin in the component (A-1) is 1, 3, 5-triazine derivative epoxy resin.

[5]

A casing for an optical semiconductor element that is formed of the light-reflecting white heat-curable epoxy resin composition as set forth in any one of [1] to [4].

[6]

An optical semiconductor device including the casing for an optical semiconductor element as set forth in [5].

The white heat-curable epoxy resin composition of the present invention is capable of forming a cured product that can maintain a high reflectivity as well as a high whiteness level over a long period of time. Accordingly, the white heat-curable epoxy resin composition of the present invention is useful as a light-reflecting material used for semiconductor devices, particularly for LED or the like.

### DETAILED DESCRIPTION OF THE INVENTION

A further detailed description of the present invention is presented below.

### (A-1) Triazine Derivative Epoxy Resin

A component (A) is a prepolymer obtained by a reaction of triazine derivative epoxy resin as a component (A-1) and acid anhydride as a component (A-2). Since a cured product of the resin composition of the present invention includes a reaction product obtained by a reaction of triazine derivative epoxy resin as the component (A-1) and acid anhydride as the component (A-2), the cured product obtained can have various effects, such as suppression of yellowing that may occur when placed under a high temperature, improvement in handling property, and prevention of foaming of a molded product that may be caused by generation of carbon dioxides derived from an acid anhydride backbone during storage at a high temperature.

A compounding ratio of the triazine derivative epoxy resin (A-1) to the acid anhydride (A-2), i.e., a ratio of (a total sum of all the epoxy groups in the component (A-1))/(a total sum of all the acid anhydride groups in the component (A-2)) is preferably 0.6 to 2, more preferably 0.8 to 1.9, and even more preferably 1.0 to 1.8. If this compounding ratio is smaller than the lower limit, an unreacted amount of the acid anhydride may remain in the cured product, and a moisture resistance of the cured product obtained may be impaired. In addition, if the compounding ratio is larger than the above upper limit, curing failure may occur, and the reliability of the cured product may thus decrease.

Reaction between the component (A-1) and the component (A-2) may preferably proceed under the presence of a hereinafter-described antioxidant as a component (E) and/or a hereinafter-described curing accelerator (D). When the triazine derivative epoxy resin (A-1) is reacted with the acid anhydride (A-2) at the abovementioned rate, there can be obtained a solid product (i.e., prepolymer). Then, it is preferred that the solid product be used in the form of a fine powder obtained by, for example, crushing such solid product. The particle diameter of the fine powder is preferably in the range of 5 μm to 3 mm.

More specifically, the aforementioned prepolymer can be obtained by a reaction of the components (A-1) and (A-2), preferably at 60 to 120° C., more preferably at 70 to 110° C., preferably for 4 to 20 hours, more preferably for 6 to 15 hours. As mentioned above, an antioxidant as the hereinafter-described component (E) may be added in advance to the reaction product of the components (A-1) and (A-2).

Alternatively, the components (A-1) and (A-2); and the hereinafter-described curing accelerator (D) may be reacted with one another at 30 to 80° C., preferably at 40 to 70° C., for 2 to 12 hours, preferably for 3 to 8 hours in advance. At that time, an antioxidant as the component (E) may be added to the reaction product in advance. A solid product as a prepolymer can be obtained through the above reaction.

It is preferred that such solid product have a softening point of 40 to 100° C., preferably 45 to 70° C. If the softening point of such prepolymer is lower than 40° C., the solid product easily aggregates, resulting in difficulties in handling the same. If the softening point is higher than 100° C., the fluidity of the composition required when molding takes place may be too low. The softening point of the solid product can be adjusted as follows. Specifically, since there is a correlation between softening point and resin viscosity, the reaction may be stopped and the prepolymer may be taken out once it has been confirmed that the resin has reached a target viscosity during the reaction. As described above, it is desirable that the solid product be turned into the form of a fine powder through, for example, crushing, before being mixed with the compositions of the present invention.

One favorable example of such triazine derivative epoxy resin (A-1) is a 1,3,5-triazine nucleus derived epoxy resin. Specifically, an epoxy resin having an isocyanurate ring is superior in light resistance and electrical insulation property, and it is preferred that such epoxy resin have a divalent epoxy group, more preferably a trivalent epoxy group with respect to one isocyanurate ring. Specific examples of such epoxy resin include tris (2,3-epoxypropyl) isocyanurate; tris (α-methylglycidyl) isocyanurate and the like. It is preferred that the triazine derivative epoxy resin of the present invention have a softening point of 40 to 125° C. Note that the aforementioned triazine derivative epoxy resins of the present invention do not include those whose triazine rings have been hydrogenated.

### (A-2) Acid Anhydride

An acid anhydride as the component (A-2) of the present invention serves as a curing agent for the triazine derivative epoxy resin (A-1). As such acid anhydride, there are used those from non-aromatic group and having no carbon-carbon double bond for the purpose of imparting a light resistance to the cured product. Specific examples of such acid anhydride include hexahydrophthalic acid anhydride; methylhexahydrophthalic acid anhydride; trialkyltetrahydrophthalic acid anhydride and hydrogenated methylnadic anhydride. Among them, hexahydrophthalic acid anhydride and methylhexahydrophthalic acid anhydride are preferred. One of these acid anhydrides may be used alone, or two or more kinds of these acid anhydrides may be used in combination.

When synthesizing the aforementioned prepolymer, an epoxy resin(s) other than the component (A-1) can also be used in combination if necessary, in an amount equal to or smaller than a certain amount within the range where the effects of the present invention will not be affected.

Examples of such epoxy resin include a bisphenol A epoxy resin; a bisphenol F epoxy resin; a biphenol epoxy resin such as a 3,3′,5,5′-tetramethyl-4,4′-biphenol epoxy resin and a 4,4′-biphenol epoxy resin; a phenolic novolac epoxy resin; a cresol novolac epoxy resin; a bisphenol A novolac epoxy resin; a naphthalenediol epoxy resin; a trisphenylol methane epoxy resin; a tetrakisphenylol ethane epoxy resin; an epoxy resin obtained by hydrogenating the aromatic ring of a phenol dicyclopentadiene novolac-type epoxy resin; an alicyclic epoxy resin; and a silicone-modified epoxy resin. Among these epoxy resins, desirable are a bisphenol A epoxy resin, a bisphenol F epoxy resin, an epoxy resin obtained by hydrogenating the aromatic ring thereof, an alicyclic epoxy resin, and a silicone-modified epoxy resin, in view of heat resistance and ultraviolet resistance. In addition, it is preferred that the abovementioned epoxy resins have a softening point of 50 to 100° C. for ease of performing prepolymerization and for improving handling property.

One example of the abovementioned prepolymer is a compound represented by the following general formula (1).

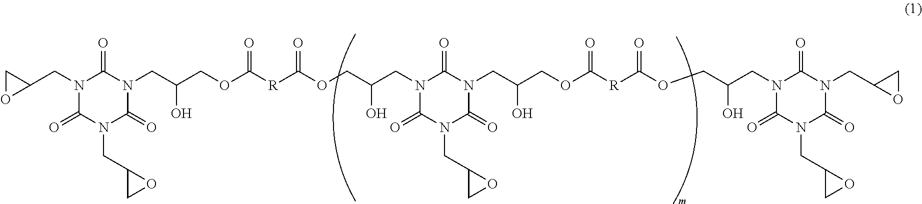

In the above formula (1), R represents an acid anhydride residue, such as that of hexahydrophthalic acid anhydride; methylhexahydrophthalic acid anhydride; trialkyltetrahydrophthalic acid anhydride or hydrogenated methylnadic anhydride; and m is an integral number of 0 to 200.

### (B) White Pigment

The present invention contains a white pigment, as it is a light-reflecting white heat-curable epoxy resin composition. A white pigment is added to increase a whiteness degree of the cured product of the composition of the present invention to thereby enhance a light reflectivity on the surface of the cured product. Examples of such white pigment include a titanium dioxide; a rare-earth oxide represented by an yttrium oxide; a zinc sulfate; a zinc oxide; a magnesium oxide; a potassium titanate; and inorganic hollow particles. Examples of inorganic hollow particles include ceramic hollow particles containing a silicon oxide based component (e.g. silica (SiO₂)) or an aluminum oxide based component (for example, alumina (Al₂O₃)), such as aerogel balloon, shirasu balloon, silica balloon and fly ash balloon; and glass balloons such as silicate soda glass, aluminosilicate glass and borosilicate soda glass. Among them, preferable are a titanium dioxide, a potassium titanate and inorganic hollow particles. Any one of these white pigments may be used alone, or two or more of them may be used in combination. Here, the average particle diameters and shapes of these white pigments are not specifically limited, but may be ones that have been conventionally known. The average particle diameter is normally from 0.05 μm to 5 μm, preferably larger than 0.05 μm and smaller than 5 μm. Particularly, the upper limit of the average particle diameter is preferably not larger than 1 μm, most preferably not larger than 0.3 μm. This average particle diameter is measured as a mass average value D₅₀ (or a median size) through a particle size distribution measurement according to a laser optical diffraction technique.

In addition, although the titanium dioxide can be that produced by any appropriate methods such as sulfuric acid method and chlorine method. However, a titanium dioxide produced by chlorine method is preferred in view of whiteness degree.

Also, it is preferred that the afore-mentioned titanium dioxide is surface-treated with alumina at least once to avoid agglomeration of the titanium dioxide particles themselves. In order to control photocatalytic ability of the titanium dioxide, enhance dispersibility or compatibility of the titanium dioxide with a resin or an inorganic filler, the titanium dioxide may preferably be further surface-treated with at least one selected from the group consisting of silica, alumina, zirconia, polyol and silicon compounds. As silicon compounds, various compounds may be applied. Examples of silicon compounds include: polysiloxanes such as polydimethylsiloxane, polymethylphenylsiloxane, polymethylhydrogensiloxane and copolymers thereof; cyclosiloxanes such as hexamethylcyclotrisiloxane, heptamethylcyclotetrasiloxane and 1,3,5,7-tetramethylcyclotetrasiloxane; chlorosilanes (e.g. trimethylchlorosilanes, dimethyldichlorosilane and methyltrichlorosilane); silane coupling agents represented by various silanes such as silanes having an epoxy functional group (e.g. 3-glycidoxypropyltrimethoxysilane, 3-glycidoxypropyltriethoxysilane, 2-(3, 4-epoxycyclohexyl) ethyltrimethoxysilane and 2-(3, 4-epoxycyclohexyl) ethyltriethoxysilane), silanes having an methacrylic group or an acryl group (e.g. 3-methacryloxypropyltrimethoxysilane, 3-methacryloxypropyltriethoxysilane, 3-acryloxypropyltrimethoxysilane, 3-acryloxypropyltriethoxysilane, methacryloxymethyltrimethoxysilane, methacryloxymethyltriethoxysilane, acryloxymethyltrimethoxysilane and acryloxymethyltriethoxysilane), silanes having a vinyl group (e.g. vinyltrichlorosilane, vinyltrimethoxysilane, vinyltriethoxysilane, vinyltris (β-methoxyethoxy) silane and vinyltriacetoxysilane), mercaptosilanes (e.g. γ-mercaptopropyltrimethoxysilane and γ-mercaptopropylmethyldimethoxysilane), silanes having an alkyl group (e.g. methyltrimethoxysilane, methyltriethoxysilane, hexyltrimethoxysilane, hexyltriethoxysilane, octyltrimethoxysilane and octyltriethoxysilane) and other silanes (e.g. γ-chloropropyltrimethoxysilane and γ-anilinopropyltrimethoxysilane); hexamethyldisiloxane; and hexamethyldisilazane.

Methods for treating the surface of the white pigment are not specifically limited. For example, surface treatment using silicon compounds may be performed by a dry method in which white pigment and silicon compounds are mixed with each other. Surface treatment using alumina, silica and the like may be performed by a wet method in which a layer is formed on the surface of the white pigment while neutralizing with sulphuric acid in an aqueous solution of sodium aluminate or sodium silicate.

The white pigment is added in an amount of preferably 3 to 300 parts by mass, and more preferably 5 to 250 parts by mass with respect to 100 parts by mass of the component (A). If the amount of the white pigment added is smaller than 3 parts by mass, the whiteness degree obtained may be insufficient. If the amount of the white pigment is larger than 300 parts by mass, formability of the resin compound may significantly decrease in addition to a decrease in the ratio of other components added to improve a mechanical strength. The white pigment is added in an amount of preferably 1 to 50% by mass, and more preferably 3 to 40% by mass with respect to the whole white heat-curable epoxy resin composition.

### (C) Inorganic Filler

An inorganic filler other than the aforementioned component (B) is further added as a component (C) to the white heat-curable epoxy resin composition of the present invention. As such inorganic filler, there can be used those that are normally added to an epoxy resin composition. Examples of such inorganic filler include silicas such as a molten silica and a crystalline silica; alumina; silicon nitride; aluminum nitride; boron nitride; antimony trioxide, but do not include the aforementioned white pigments (white coloring agent) as the component (B). While the average particle diameter and shape of these inorganic fillers are not limited, the average particle diameter is normally in a range of 3 μm to 50 μm, preferably not smaller than 5 μm and not larger than 45 μm.

As a white pigment, there may be used alumina, silica, and the like as well. When using them as one of the components of the present invention, those with an average particle diameter of 5 μm to 45 μm may be used as the inorganic filler (C), whereas those with an average particle diameter larger than 0.05 μm and smaller than 5 μm may be used as the above white pigment (B). Meanwhile, this average particle diameter is measured as an average cumulative mass D₅₀ (or a median size) through a particle size distribution measurement according to a laser optical diffraction technique.

As the component (C), there are particularly preferably used a silica-based inorganic filler such as a crushed silica and a fused spherical silica, and while the particle size thereof is not specifically limited, the fused spherical silica is preferred in view of formability and fluidity, and the average particle diameter thereof is preferably 4 to 40 μm, and particularly preferably 7 to 35 μm. In addition, it is preferred that fillers having a fine particle size of 0.1 to 3 μm, fillers having a middle particle size of 4 to 8 μm, and fillers having a coarse particle size of 10 to 50 μm be used in combination in order to achieve a high fluidity.

The aforementioned inorganic filler as the component (C) may be surface treated with a coupling agent such as a silane coupling agent and a titanate coupling agent in order to increase a bond strength with the resin component as the component (A) or with the white pigment as the component (B).

Examples of such coupling agent include an epoxy functional alkoxysilane such as γ-glycidoxypropyltrimethoxysilane, γ-glycidoxypropylmethyldiethoxyslane and β-(3,4-epoxycyclohexyl)ethyltrimethoxysilane; an amino functional alkoxysilane such as N-β(aminoethyl)-γ-aminopropyltrimethoxysilane, γ-aminopropyltriethoxysilane and N-phenyl-γ-aminopropyltrimethoxysilane; and a mercapto functional alkoxysilane such as γ-mercaptopropyltrimethoxysilane. In addition, an amount of the coupling agent used for the surface treatment and a method of the surface treatment are not specifically limited, however, preferred are the coupling agents other than those that change the color of the fillers treated when left under a temperature of greater than or equal to 150° C.

It is preferred that the amount of the inorganic filler as the component (C) be 50 to 600 parts by mass, especially 100 to 600 parts by mass with respect to 100 parts by mass of the component (A). If such amount is smaller than 50 parts by mass, the strength may not be sufficient, and if the amount is greater than 600 parts by mass, a defect such as a peeling within an element may occur due to a defect of unfilling or loss of flexibility which are caused by an increase in viscosity. This amount of the inorganic filler as the component (C) is preferably 10 to 90% by mass, particularly preferably 20 to 80% by mass, with respect to the whole amount of the white heat-curable epoxy resin composition.

### (D) Curing Accelerator

The curing accelerator as a component (D) is added in order to cure the white heat-curable epoxy resin composition. The curing accelerator is not specifically limited and those that are publicly known as curing catalysts for epoxy resin composition can be used. As such curing accelerator, there can be used tertiary amines; imidazoles; organic carboxylates of these tertiary amines and imidazoles; organic carboxylate metal salts; metal-organic chelate compounds; aromatic sulfonium salts; phosphorous curing catalysts such as organic phosphine compounds and phosphonium compounds; and salts of these phosphorous curing catalysts. Any one of these compounds may be used alone, or two or more of them may be used in combination. Among these compounds, imidazoles such as 2-ethyl-4-methylimidazole, phosphorous curing catalysts such as methyltributylphosphonium dimethylphosphate, and octylic acid salts of tertiary amines are more preferable. In addition, organic acid salts of quaternary phosphonium bromide and amine are also preferably used in combination.

As for the amount of the curing accelerator, it is preferred that the curing accelerator be added in an amount of 0.05 to 5% by mass, especially 0.1 to 2% by mass with respect to a total amount of (A). If the amount is out of these ranges, a balance between heat resistance and humidity resistance of the cured product of the epoxy resin composition may be impaired, or a curing at the time of performing molding may become extremely slow or fast.

### (E) Antioxidant

An antioxidant as a component (E) is added to the white heat-curable epoxy resin composition of the present invention for the purpose of improving an initial transmission and maintaining a transmission in the long term. As such antioxidant (E), there may be used a phenolic antioxidant, a phosphorous antioxidant and a sulfur-based antioxidant. Specific examples of such antioxidant are as follows.

Examples of such phenolic antioxidant include 2,6-di-t-butyl-p-cresol, butylated hydroxyanisole, 2,6-di-t-butyl-p-ethylphenol, stearyl-β-(3,5-di-t-butyl-4-hydroxyphenyl)propionate, 2,2′-methylenebis(4-methyl-6-t-butylphenol), 4,4′-butylidenebis(3-methyl-6-t-butylphenol), 3,9-bi s[1,1-dimethyl-2-{β-(3-t-butyl-4-hydroxy-5-methylphenyl)propionyloxy}ethyl]2,4, 8,10-tetraoxaspiro[5,5]undecane, 1,1,3-tris(2-methyl-4-hydroxy-5-t-butylphenyl)butane and 1,3,5-trimethyl-2,4,6-tris(3,5-di-t-butyl-4-hydroxybenzyl)benzene.

Examples of a phosphorous antioxidant include triphenyl phosphite, diphenylalkyl phosphite, phenyldialkyl phosphite, tri(nonylphenyl)phosphite, trilauryl phosphite, trioctadecyl phosphite, distearyl pentaerythritol diphosphite, tris(2,4-di-tert-butylphenyl)phosphite, diisodecyl pentaerythritol diphosphite, di(2,4-di-tert-butylphenyl)pentaerythritol diphosphite, tristearylsorbitol triphosphite and tetrakis(2,4-di-tert-butylphenyl)-4,4′-biphenyl diphosphonate, and 3,9-bis(octadecyloxy)-2,4,8,10-tetraoxa-3,9-diphosphaspiro[5.5]undecane.

Examples of a sulfur-based antioxidant include dilauryl thiodipropionate, distearyl thiodipropionate, and dibenzyl disulfide.

These antioxidants may be used alone, or two or more kinds of these antioxidants may be used in combination. It is preferred that the antioxidant be added in an amount of 0.01 to 10% by mass, especially 0.1 to 8% by mass with respect to the component (A). If the amount is too small, a color may change due to an insufficient heat resistance, and if the compound amount is too large, sufficient curability and strength may not be achieved due to a curing inhibition.

(F) Hydrotalcite-Like Compound and/or Calcined Product of Hydrotalcite-Like Compound.

The white heat-curable epoxy resin composition of the present invention contains a hydrotalcite-like compound and/or a calcined product of a hydrotalcite-like compound (F), in order to trap anions such as carbonyl ions, or to bring the pH of the composition close to neutrality. Here, the hydrotalcite-like compound is a layered double hydroxide represented by, for example, the following composition formula (2).

[M²⁺₁₋ₓM³⁺ₓ(OH)₂]^{x+}[(Aⁿ⁻_{x/n}).mH₂O]^{x-} (2)

In the above formula (2), M²⁺ represents divalent metal ions such as Mg²⁺, Ca²⁺, Zn²⁺, Co²⁺, Ni²⁺,Cu²⁺ and Mn²⁺. M³⁺ represents trivalent metal ions such as Al³⁺, Fe³⁺ and Cr³⁺. Aⁿ⁻ represents n-valent anions such as OH⁻,Cl⁻,CO₃²⁻,SO₄²⁻ in which x represents a number larger than 0, preferably 0.10 to 0.50, more preferably 0.20 to 0.33; and m represents a number of 0 or above, preferably 0 to 10, more preferably 0 to 4.

The calcined product of the hydrotalcite-like compound is a double oxide represented by, for example, the following general formula (3) as below.

M²⁺₁₋ₓM³⁺ₓO_{1+x/2} (3)

In the formula (3), M²⁺ and x denote the same as those defined by formula (2).

Alternatively, there may be used a zinc-modified hydrotalcite-based compound such as Mg₃ZnAl₂(OH)₁₂CO₃.wH₂O (w is a real number) and Mg₃ZnAl₂(OH)₁₂CO₃.

The hydrotalcite-like compound and the calcined product of a hydrotalcite-like compound as the component (F) have anion exchange ability. Thus, it is possible to prevent deterioration of resin components after curing, by trapping carbonyl ions such as formic acid ions and acetic acid ions derived from the component (A), or by bringing the pH of the cured product close to neutrality.

The component (F) is preferably a hydrotalcite-like compound represented by the following formula (4) and/or the calcined product of such hydrotalcite-like compound.

MgₐAl_{b}(OH)_{c}CO₃.nH₂O (4)

In the formula (4), a, b and c represent numbers larger than 0, provided that 2a+3b-c=2, and n represents a number satisfying an inequality: 0≦n≦4.

Examples of the hydrotalcite compounds represented by formula (4) include: Mg_{4.5}Al₂(OH)₁₃CO₃3.5H₂O, Mg_{4.5}Al₂(OH)₁₃CO₃, Mg₄Al₂(OH)₁₂CO₃3.5H₂O, Mg₆Al₂(OH)₁₆CO₃.4H₂O, Mg₅Al₂(OH)₁₄CO₃.4H₂O, Mg₃Al₂(OH)₁₀CO₃.1.7H₂O. Examples of the names of the commercially available products thereof may include: “DHT-4A”, “DHT-4A-2”, “DHT-4C” “DHT-6” and “KYOWADO500” (all by KYOWA CHEMICAL INDUSTRY CO., LTD) or “STABIACE HT-1”, “STABIACE HT-7” and “STABIACE HT-P” (by Sakai Chemical Industry Co., Ltd).

The amount of the component (F) to be added is 1 to 10 parts by mass, preferably 2 to 8 parts by mass with respect to 100 parts by mass of the component (A). If the amount of the component (F) to be added is less than this lower limit, there cannot be obtained a sufficient effect, and if the component (F) is added in an amount more than this upper limit, there may be caused a reduction in curability and/or adhesion.

Alternatively, white heat-curable epoxy resin composition of the present invention may further contain, in addition to the above components (A) to (F), the following optional components:

### (G) Mold Release Agent

A mold release agent may be added to the white heat-curable epoxy resin composition of the present invention. A mold release agent as a component (G) is added for the purpose of improving a mold releasing property after molding.

While as such mold release agent, there are known a natural wax such as carnauba wax, an acid wax, a polyethylene wax and a synthetic wax such as fatty acid ester, many of them are, when exposed to a high temperature and/or light irradiation, often susceptible to yellowing and may deteriorate with time such that their mold releasing properties will be lost. Therefore, a glycerin derivative and fatty acid ester which hardly change their color are preferred, and further, there is preferred carnauba wax which hardly changes its color with the lapse of time although it is colored a bit in the early stages. Particularly preferred are glycerin monostearate and stearyl stearate which hardly change their colors with the lapse of time although they are colored a bit in the early stages.

It is preferred that the mold release agent (G) be added in an amount of 0.05 to 7.0% by mass, especially 0.1 to 5.0% by mass with respect to the total sum of the component (A). If the mold release agent (G) is added in an amount of smaller than 0.05% by mass, there may not be achieved a sufficient mold releasing property. On the other hand, the amount of the mold release agent (G) being greater than 7.0% by mass may lead to bleeding failures, adhesion failures or the like.

### (H) Coupling Agent

A coupling agent such as a silane coupling agent and a titanate coupling agent may be added to the white heat-curable epoxy resin composition of the present invention for the purpose of improving a bond strength between the resin and the inorganic filler and an adhesion between the resin composition and a metal. Preferred examples of such coupling agents include an epoxy functional alkoxysilane such as γ-glycidoxypropyltrimethoxysilane, γ-glycidoxypropylmethyldiethoxysilane and β-(3,4-epoxycyclohexyl)ethyltrimethoxysilane; and a mercapto functional alkoxysilane such as γ-mercaptopropyltrimethoxysilane. Meanwhile, those causing a resin to discolor when left under a temperature of not lower than 150° C. are not preferable as is the case with an amine-based silane coupling agent.

It is preferred that the coupling agent as a component (H) be added in an amount of 0.1 to 8.0% by mass, especially 0.5 to 6.0% by mass with respect to the component (A). When the component (H) added is in an amount of smaller than 0.1% by mass, an adhesion effect to the base material will be insufficient. On the other hand, the amount thereof being greater than 8.0% by mass may lead to an extremely low viscosity, which can be the cause of voids.

### (I) Other Additive Agents

A wide variety of additive agents can be further added to the white heat-curable epoxy resin composition of the present invention as needed, without impairing the effects of the invention. For example, a reinforcing material such as glass fiber can be added in order to improve the property of the resin. Also, other additive agents such as a silicone powder, a silicone oil, an acrylic resin-like thermoplastic resin, a thermoplastic elastomer, an organic synthetic rubber and a light stabilizer may be added.

An example of the production method of the white heat-curable epoxy resin composition of the present invention is such that the prepolymer (A), the white pigment (B), the inorganic filler (C), the curing catalyst (D), the antioxidant (E), the hydrotalcite-like compound and/or the calcined product of a hydrotalcite-like compound (F) and other additives are combined with one another at a given composition ratio, and then a mixer or the like is used to mix such combined product to a sufficiently uniform level, followed by melting and mixing the same through a heat roll, a kneader, an extruder or the like. A product thus obtained is then cooled and solidified, followed by crushing the same into pieces of an appropriate size, thus obtaining the molding material of the white heat-curable epoxy resin composition.

Examples of the most common molding method using the white heat-curable epoxy resin composition of the present invention include a transfer molding method and a compression molding method. The transfer molding method uses a transfer molding machine, and it is preferred that transfer molding be performed under a condition of a molding pressure of 5 to 20 N/mm², a molding temperature of 120 to 190° C. and a molding time of 30 to 500 sec, especially under a molding temperature of 150 to 185° C. and a molding time of 30 to 180 sec. Meanwhile, the compression molding method uses a compression molding machine, and it is preferred that compression molding be performed under a molding temperature of 120 to 190° C. and a molding time of 30 to 600 sec, especially under a molding temperature of 130 to 160° C. and a molding time of 120 to 300 sec. In addition, in each of the molding methods, a post curing may be performed at 150 to 185° C. for 0.5 to 20 hours.

The white heat-curable epoxy resin composition of the present invention may be used for encapsulating a normal semiconductor or various modules for automobile use. In such cases, carbon black or the like may be used as a coloring agent. Although any carbon blacks commercially available can be used, those having high purity and not containing a large amount of alkali metal or halogen are desired.

### Working Examples

The present invention is described in detail hereunder with reference to working and comparative examples, however, the present invention is not limited to the following working examples.

The materials that were used in the working and comparative examples are as follows.
(A) Prepolymer
   (A-1) Triazine derivative epoxy resin
      (A-1-1): Tris (2,3-epoxypropyl) isocyanurate (product name: TEPIC-S by Nissan Chemical Industries, Ltd.)
   (A-2) Acid anhydride
      (A-2-1): Methylhexahydrophthalic anhydride (product name: RIKACID MH by New Japan Chemical Co., Ltd.)
      (A-2-2): Hexahydrophthalic anhydride (product name: RIKACID HH by New Japan Chemical Co., Ltd.)
      (A-2-3): 1,2,3,6-tetrahydrophthalic anhydride (product name: RIKACID TH by New Japan Chemical Co., Ltd.)
(B) White pigment
   (B-1): Titanium dioxide treated with alumina/silica/polyol (product name: CR-90 by ISHIHARA SANGYO KAISHA, LTD.; average particle diameter 0.25 μm)
(C) Inorganic filler
   (C-1): Fused spherical silica (product name: MAR-T815/53C by Tatsumori Ltd.; average particle diameter 10 μm)
(D) Curing accelerator
   (D-1): Phosphorous curing catalyst; Quaternary phosphonium bromide (product name: U-CAT5003 by SAN APRO CO., LTD.)
(E) Antioxidant
   (E-1): Phosphorous antioxidant (product name: PEP-8 by ADEKA CORPORATION)
(F) Hydrotalcite-like compound and/or calcined product of hydrotalcite-like compound
   (F-1): calcined product of (Mg)₆Al₂(CO₃)(OH)₁₆.4H₂O (product name: DHT-4A-2 by KYOWA CHEMICAL INDUSTRY CO., LTD.)
   (F-2): (Mg)_{4.3}Al₂(CO₃)(OH)_{12.6}.mH₂O (product name: DHT-4A by KYOWA CHEMICAL INDUSTRY CO., LTD.)
(G) Mold release agent
   (G-1): Stearyl stearate (product name: SL-900A by RIKEN VITAMIN CO., LTD.)
(H) Coupling agent
   (H-1): 3-mercaptopropyltrimethoxysilane (product name: KBM-803 by Shin-Etsu Chemical Co., Ltd.)

### Example of Synthesis 1

### Epoxy Resin Prepolymer (Production of the Component (A))

Prepolymers A to D of the component (A) were synthesized by combining the above-mentioned material components at the ratios shown in Table 1, followed by using a gate mixer to heat the combined product under the reaction condition shown in Table 1 so as to allow the epoxy resin (A-1) to react with the acid anhydride (A-2).

TABLE 1

| Compounding amount | | | | | | |
|---|---|---|---|---|---|---|
| (parts by mass) | | | Prepolymer A | Prepolymer B | Prepolymer C | Prepolymer D |
| (A-1) | Epoxy resin | A-1-1 | 43.6 | 39.1 | 45.6 | 45.7 |
| (A-2) | Acid anhydride | A-2-1 | 56.4 | 60.9 | | |
| | | A-2-2 | | | 54.4 | |
| | | A-2-3 | | | | 54.3 |

| | | | | |
|---|---|---|---|---|
| Epoxy group equivalent/Acid | 1.4 | 1.2 | 1.4 | 1.4 |
| anhydride group equivalent | | | | |
| Reaction condition | 80° C., | 80° C., | 80° C., | 80° C., |
| | 10 hours | 10 hours | 10 hours | 10 hours |

### Working Examples 1 to 5, and Comparative Examples 1 to 6

Each sample was prepared by using a hot twin-roll to melt and mix the components combined at the rates (parts by mass) shown in Table 2 (working examples) and Table 3 (comparative examples), followed by cooling and crushing the same so as to obtain the heat-curable epoxy resin compositions. The following characteristics of these compositions were measured. Tables 2 and 3 show the results thereof.

### Handling Property of Composition

Handling properties at the time of performing melting and mixing using the hot twin-roll were evaluated by the criteria that: when there could be obtained a composition capable of being easily tableted after all the components had been uniformly mixed, it was marked “OK”; and when there could only be obtained a composition incapable of being easily tableted after all the components had been uniformly mixed, it was marked “NG”.

### Spiral Flow Value and Preservation Stability

A spiral flow value was measured by using a mold manufactured in accordance with the EMMI standard, under the condition of a molding temperature of 175° C., a molding pressure of 6.9 N/mm² and a molding time of 90 sec. Further, a similar measurement was performed relative to a specimen of each example after having stored such specimen in an incubator at 25° C. for 24 hours or 48 hours, to confirm the preservation stability thereof.

### Room-Temperature Bending Strength, Room-Temperature Bending Elastic Modulus

A mold manufactured in accordance with JIS-K6911 standard was used to perform molding under the condition of a molding temperature of 175° C., a molding pressure of 6.9 N/mm² and a molding time of 90 sec, followed by performing post curing at 150° C. for two hours. The bending strength and bending elastic modulus of the post-cured specimen were measured at a room temperature (25° C.).

### Light Reflection Rate and Heat Resistance

A cured product having a size of 50 mm per side and a thickness of 1.0 mm was formed under the condition of a molding temperature of 175° C., a molding pressure of 6.9 N/mm² and a molding time of 90 sec, which was then subjected to secondary curing at 150° C. for 2 hours, followed by using an X-rite 8200 by S.D.G K.K to measure an initial light reflection rate thereof at 450 nm. And then, each specimen was subjected to a heat treatment at 180° C. for 168 hours or 336 hours, followed by measuring the light reflection rate thereof at 450 nm with the aid of the X-rite 8200 by S.D.G K.K. in a similar manner.

TABLE 2

| | | | | Working examples | | | | |
|---|---|---|---|---|---|---|---|---|
| Compounding amount (parts by mass) | | | | 1 | 2 | 3 | 4 | 5 |
| (A) | Prepolymer | | Prepolymer A | 100.0 | 100.0 | 100.0 | | |
| | | | Prepolymer B | | | | 100.0 | |
| | | | Prepolymer C | | | | | 100.0 |
| | | | Prepolymer D | | | | | |
| (B) | White pigment | | B-1 | 90.0 | 90.0 | 90.0 | 90.0 | 90.0 |
| (C) | Inorganic filler | | C-1 | 410.0 | 410.0 | 410.0 | 410.0 | 410.0 |
| (D) | Curing accelerator | | D-1 | 0.8 | 0.8 | 0.8 | 0.8 | 0.8 |
| (E) | Antioxidant | | E-1 | 2.5 | 2.5 | 2.5 | 2.5 | 2.5 |
| (F) | Hydrotalcite-like compound | | F-1 | 2.5 | 5.0 | | 2.5 | 8.0 |
| | | | F-2 | | | 2.5 | | |
| (G) | Mold release agent | | G-1 | 2.0 | 2.0 | 2.0 | 2.0 | 2.0 |
| (H) | Coupling agent | | H-1 | 0.5 | 0.5 | 0.5 | 0.5 | 0.5 |
| Characteristic | Handling property | | | OK | OK | OK | OK | OK |
| evaluation | Spiral flow | Initial value | inch | 40 | 37 | 40 | 45 | 30 |
| | value | 25° C. 24 hours | inch | 32 | 29 | 33 | 36 | 24 |
| | | 25° C. 48 hours | inch | 24 | 20 | 23 | 27 | 18 |
| | Room-temperature bending | | MPa | 95 | 94 | 95 | 90 | 110 |
| | strength | | | | | | | |
| | Room-temperature bending | | MPa | 16000 | 16200 | 16400 | 16000 | 17500 |
| | elastic modulus | | | | | | | |
| | Light | Initial value | % | 95 | 95 | 94 | 95 | 92 |
| | reflection | 180° C. 168 hours | % | 75 | 80 | 74 | 80 | 81 |
| | rate | 180° C. 336 hours | % | 69 | 72 | 65 | 72 | 70 |

TABLE 3

| | | | | Comparative examples | | | | | |
|---|---|---|---|---|---|---|---|---|---|
| Compounding amount (parts by mass) | | | | 1 | 2 | 3 | 4 | 5 | 6 |
| (A) | Prepolymer | | Prepolymer A | 100.0 | | | | | |
| | | | Prepolymer C | | 100.0 | | | | |
| | | | Prepolymer D | | | 100.0 | | | |
| (A-1) | Epoxy resin | | A-1-1 | | | | 43.6 | 45.7 | 45.7 |
| (A-2) | Acid anhydride | | A-2-1 | | | | 56.4 | | |
| | | | A-2-3 | | | | | 54.3 | 45.3 |
| (B) | White pigment | | B-1 | 100.0 | 100.0 | 100.0 | 100.0 | 100.0 | 100.0 |
| (C) | Inorganic filler | | C-1 | 400.0 | 400.0 | 400.0 | 400.0 | 400.0 | 400.0 |
| (D) | Curing accelerator | | D-1 | 0.8 | 0.8 | 0.8 | 0.8 | 0.8 | 0.8 |
| (E) | Antioxidant | | E-1 | 2.5 | 2.5 | 2.5 | 2.5 | 2.5 | 2.5 |
| (F) | Hydrotalcite-like compound | | F-1 | | | 2.5 | | | 5.0 |
| | | | F-2 | | | | | | |
| (G) | Mold release agent | | G-1 | 2.0 | 2.0 | 2.0 | 2.0 | 2.0 | 2.0 |
| (H) | Coupling agent | | H-1 | 0.5 | 0.5 | 0.5 | 0.5 | 0.5 | 0.5 |
| Characteristic | Handling property | | | OK | OK | OK | NG | OK | OK |
| evaluation | Spiral | Initial value | inch | 40 | 42 | 31 | Handling | 60 | 65 |
| | flow | 25° C. 24 hours | inch | 25 | 30 | 20 | property | 42 | 48 |
| | value | 25° C. 48 hours | inch | 18 | 23 | 15 | too poor | 30 | 33 |
| | Room-temperature bending | | MPa | 95 | 92 | 110 | to | 115 | 106 |
| | strength | | | | | | evaluate | | |
| | Room-temperature bending | | MPa | 16000 | 16500 | 17600 | moldability | 17400 | 17600 |
| | elastic modulus | | | | | | | | |
| | Light | Initial value | % | 95 | 93 | 90 | | 88 | 90 |
| | reflection | 180° C. 168 hours | % | 60 | 65 | 60 | | 49 | 62 |
| | rate | 180° C. 336 hours | % | 50 | 57 | 51 | | 42 | 53 |

As shown in Tables 2 and 3, it could be confirmed that the handling properties had been improved by prepolymerization. Also, since the resin cured product according to the foregoing embodiments contain a hydrotalcite-like compound and/or a calcined product of a hydrotalcite-like compound, not only the heat resistance was improved but also preservation stability was improved as a secondary effect due to the decreased influence by impurities.

What is claimed:

1. A light-reflecting white heat-curable epoxy resin composition capable of being pressure-molded at a room temperature, comprising:
(A) a prepolymer as a reaction product of a triazine derivative epoxy resin (A-1) and a non-aromatic and carbon-carbon double bond-free acid anhydride (A-2), wherein a ratio of a total sum of epoxy groups in the component (A-1) to a total sum of acid anhydride groups in the component (A-2) is 0.6 to 2.0;
(B) a white pigment;
(C) an inorganic filler other than the white pigment (B);
(D) a curing accelerator;
(E) at least one antioxidant selected from a phenolic antioxidant, a phosphorous antioxidant and a sulfur-based antioxidant; and
(F) a hydrotalcite-like compound and/or a calcined product of a hydrotalcite-like compound.

2. The light-reflecting white heat-curable epoxy resin composition according to claim 1, wherein the hydrotalcite-like compound and/or the calcined product of the hydrotalcite-like compound (F) is represented by the following general formula (4):
MgₐAl_{b}(OH)_{c}CO₃.nH₂O (4)
wherein a, b and c represent numbers larger than 0, provided that 2a+3b-c=2, and n represents a number satisfying an inequality: 0≦n≦4.

3. The light-reflecting white heat-curable epoxy resin composition as set forth in claim 1, wherein the white pigment (B) is a titanium dioxide that has been surface-treated with alumina, and further with at least one selected from the group consisting of silica, alumina, zirconia, polyol and a silicon compound.

4. The light-reflecting white heat-curable epoxy resin composition as set forth in claim 2, wherein the white pigment (B) is a titanium dioxide that has been surface-treated with alumina, and further with at least one selected from the group consisting of silica, alumina, zirconia, polyol and a silicon compound.

5. The light-reflecting white heat-curable epoxy resin composition as set forth in claim 1, wherein the triazine derivative epoxy resin as the component (A-1) is 1,3,5-triazine derivative epoxy resin.

6. The light-reflecting white heat-curable epoxy resin composition as set forth in claim 2, wherein the triazine derivative epoxy resin as the component (A-1) is 1,3,5-triazine derivative epoxy resin.

7. The light-reflecting white heat-curable epoxy resin composition as set forth in claim 3, wherein the triazine derivative epoxy resin as the component (A-1) is 1,3,5-triazine derivative epoxy resin.

8. The light-reflecting white heat-curable epoxy resin composition as set forth in claim 4, wherein the triazine derivative epoxy resin as the component (A-1) is 1,3,5-triazine derivative epoxy resin.

9. A casing for an optical semiconductor element that is formed of the light-reflecting white heat-curable epoxy resin composition as set forth in claim 1.

10. A casing for an optical semiconductor element that is formed of the light-reflecting white heat-curable epoxy resin composition as set forth in claim 2.

11. An optical semiconductor device comprising the casing for an optical semiconductor element as set forth in claim 9.

12. An optical semiconductor device comprising the casing for an optical semiconductor element as set forth in claim 10.
